(19) United States
(12) Patent Application Publication
(10) Pub. No.: US 2021/0264930 A1
(43) Pub. Date: Aug. 26, 2021

(54) Sound Processing Method

(71) Applicant: Yamaha Corporation, Hamamatsu-shi (JP)

(72) Inventor: Kosuke SAITO, Hamamatsu-shi (JP)

(21) Appl. No.: 17/180,134

(22) Filed: Feb. 19, 2021

(30) Foreign Application Priority Data
Feb. 21, 2020 (JP) 2020-027934

(51) Int. Cl. G10L 21/0208; H04R 3/00; H04R 1/10

(52) U.S. Cl. CPC G10L 21/0208; G10L 2021/02082; H04R 1/1083; H04R 3/002

(57) ABSTRACT

A sound processing method includes accepting a plurality of setting points, accepting from a user a first operation and a second operation, and adjusting gain values. The first operation includes selecting any one of a plurality of first setting points belonging to a region having a gain value higher than a reference gain value or a plurality of second setting points belonging to a region having a gain value lower than the reference gain value. The second operation includes adjusting the gain value of each of the plurality of first setting points or each of the plurality of second setting points selected. The gain values are values of each of the plurality of first setting points or each of the plurality of second setting points selected in the first operation according to the second operation.

### CROSS REFERENCE TO RELATED APPLICATIONS

This Nonprovisional application claims priority under 35 U.S.C. § 119(a) on Patent Application No. 2020-027934 filed in Japan on Feb. 21, 2020, the entire contents of which are hereby incorporated by reference.

### BACKGROUND

### Technical Field

One embodiment of the present disclosure relates to processing of an input audio signal.

### Background Information

Conventionally, there has been an audio reproduction device having a function of a graphic equalizer and adjusting the frequency characteristics of one or more frequency bands. In the conventional audio reproduction device, operators are displayed on a screen, each of the operators adjusting the frequency characteristics of an audio signal for each of a plurality of frequency bands, and a user operates each of the operators.

### SUMMARY

The user may want to adjust the gain values of the plurality of frequency bands (for example, gain values of 0 dB or more) collectively among the frequency characteristics in some cases. However, in the conventional device, the user operates the operator of each frequency band individually. For this reason, the user finds difficulty in adjusting the gain values of the plurality of frequency bands at once and feels troublesomeness.

One embodiment of the present disclosure aims to provide a sound processing method that can collectively operate the frequency characteristics of a plurality of frequency bands.

The sound processing method according to one embodiment of the present disclosure includes: accepting a plurality of setting points each setting a gain value for each band; accepting from a user a first operation and a second operation, the first operation including selecting, from among the plurality of setting points that are accepted, any one of a plurality of first setting points belonging to a region having a gain value higher than a reference gain value or a plurality of second setting points belonging to a region having a gain value lower than the reference gain value, and the second operation including adjusting the gain value of each of the plurality of first setting points or each of the plurality of second setting points selected in the first operation; and adjusting the gain value of each of the plurality of first setting points or each of the plurality of second setting points selected in the first operation according to the second operation.

Further, the sound processing method includes accepting a selection of a setting point for each band and an operation of adjusting a gain value at the setting point.

Further, the sound processing method includes: accepting a plurality of setting points each setting a gain value for each band; and from among the plurality of setting points that are accepted, accepting from a user a first touch operation of selecting a part of the setting points, a second touch operation of selecting all the setting points in a mode different from a mode of the first operation, and a third operation of adjusting the gain value of each of the one or plurality of setting points selected by the first touch operation or the second touch operation.

Further, the sound processing method includes: accepting a plurality of setting points each setting a gain value for each band; among the plurality of setting points, accepting from a user a selection touch operation of selecting the one or plurality of setting points, and an adjustment touch operation of adjusting the gain value of each of the one or plurality of setting points selected by the selection touch operation; detecting, in the adjustment touch operation, a first distance between an initial touch position of the user and a position corresponding to a reference gain value, and a second distance between a position reached by maintaining touching from the initial touch position and the position corresponding to the reference gain value; and performing a first adjustment mode of adjusting the gain value of each of the one or plurality of setting points selected by the selection touch operation according to a ratio between the first distance and the second distance.

According to one embodiment of the present disclosure, the frequency characteristics of the plurality of frequency bands can be operated collectively. Other objects and novel features of the present disclosure will become apparent with reference to following drawings, in which:

### BRIEF DESCRIPTION OF THE DRAWINGS

FIG. 1 is a block configuration diagram showing a main configuration of a mixer;

FIG. 2 is an external view showing an example of the external appearance of an operation panel of the mixer;

FIG. 3 is an explanatory diagram showing an example of a first operation and a second operation on a touch panel;

FIG. 4 is an explanatory diagram showing an example of the first operation and the second operation on the touch panel and different from the example of FIG. 3;

FIG. 5 is a flowchart showing an example of setting point selection processing;

FIG. 6 is a flowchart showing an example of gain value adjustment processing;

FIG. 7 is an explanatory diagram showing an example of adjusting the gain value of one setting point;

FIG. 8 is an explanatory diagram showing an example of adjusting the gain values of all the setting points;

FIG. 9 is a flowchart showing an example of sound processing of another mixer;

FIG. 10 is a flowchart showing an example of the operation of the mixer when a single touch is accepted;

FIG. 11 is a flowchart showing an example of the operation of the mixer when a two-finger touch is accepted;

FIG. 12 is a flowchart showing an example of the operation of the mixer when a four-finger touch is accepted;

FIG. 13 is an explanatory diagram showing an example of restoring a changed equalization (EQ) curve to an EQ curve obtained before being changed;

FIG. 14 is an explanatory diagram illustrating an operation of the gain value adjustment processing of a first modification;

FIG. 15 is an explanatory diagram showing a screen of the gain value adjustment processing of a second modification;

and

FIG. 16 is an explanatory diagram showing a screen of the gain value adjustment processing of a third modification.

### DETAILED DESCRIPTION

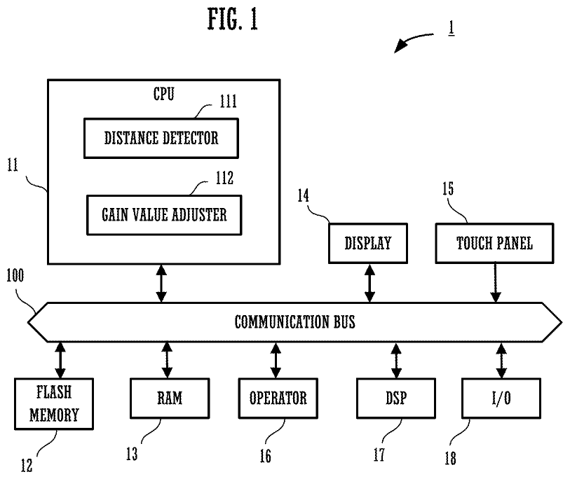

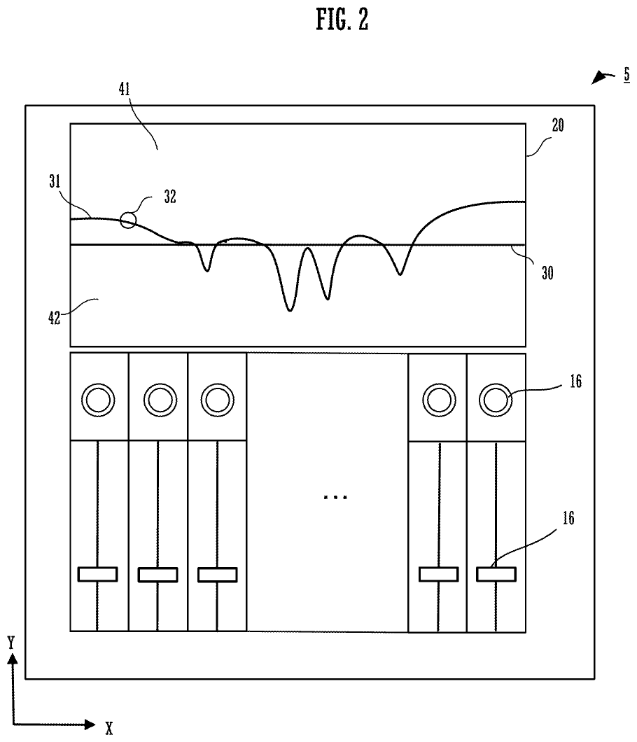

FIG. 1 is a block diagram showing a main configuration of a mixer 1 according to the present embodiment. FIG. 2 is an external view showing an example of the external appearance of an operation panel 5 of the mixer 1.

As shown in FIG. 1, a mixing console (hereinafter referred to as the mixer 1) includes a central processing unit (CPU) 11, a flash memory 12, a random access memory (RAM) 13, a display 14, a touch panel 15, an operator 16, a digital signal processor (DSP) 17, and an input/output (I/O) 18. The CPU 11, the flash memory 12, the RAM 13, the display 14, the touch panel 15, the operator 16, the DSP 17, and the I/O 18 are connected to each other via a bus 100. The mixer 1 referred to in this example is an example of a parameter setting device of the present disclosure.

The CPU 11 executes various operations by reading a predetermined program stored in the flash memory 12 into the RAM 13. The program does not need to be stored in the flash memory 12 of the own device. The CPU 11 may download a program from another device such as a server (not shown) each time and read the program into the RAM 13.

Further, the CPU 11 includes a distance detector 111 and a gain value adjuster 112. The CPU 11 reads a program related to distance detection and a program related to gain value adjustment from the flash memory 12 into RAM 13. With this configuration, the CPU 11 constitutes the distance detector 111 and the gain value adjuster 112. The distance detector 111 and the gain value adjuster 112 are described later.

The display 14 has a liquid crystal display (LCD) provided on the operation panel 5. As shown in FIG. 2, the display 14 displays an equalizer setting screen 20 showing various information, such as the frequency characteristics of an equalizer, according to an instruction of the CPU 11. In addition, the display 14 displays a screen that reflects the content of a user operating the touch panel 15.

The display 14 displays a reference gain value 30 and a curve (hereinafter, referred to as an EQ curve 31) showing the frequency characteristics of the equalizer (see FIG. 2). In this example, the reference gain value 30 is 0 dB. The equalizer setting screen 20 shows the frequency in the X-axis direction and the gain value in the Y-axis direction. The equalizer setting screen 20 is divided into a boost region (first region) 41 on the plus gain side and a cut region 42 (second region) on the minus gain side with respect to the reference gain value 30. Note that the EQ curve 31 in FIG. 2 shows the characteristics used last time read from the flash memory 12.

The touch panel 15 is stacked on the LCD of the display 14 to constitute a graphical user interface (GUI). The touch panel 15 accepts various operations from the user. In this example, the touch panel 15 accepts the operation such as the user touching or sliding the operation surface. The touch panel 15 referred to in this example is an example of a setting point acceptor and an operation acceptor of the present disclosure.

In this example, the touch panel 15 is a capacitive type touch panel that determines the presence of touch operation and the touch position based on the change in capacitance when the user touches the operation surface. For example, the touch panel 15 acquires the coordinates of the touch position based on two orthogonal axes (X-axis and Y-axis).

The operator 16 is a physical operator provided on the operation panel 5. A plurality of operators 16 are provided on the operation panel 5. The operator 16 is, for example, a knob (rotary operator) or a fader.

The DSP 17 performs various types of signal processing on an input audio signal. The DSP 17 uses an equalizer function or the like to impart the frequency characteristics corresponding to the EQ curve 31 to the input audio signal. That is, the DSP 17 changes the frequency characteristics given to the audio signal when the EQ curve 31 is changed by a user operation.

The I/O 18 is an interface of the external device connected to the mixer 1. The I/O 18 is connected to a microphone or the like and inputs a sound signal. Further, the I/O 18 is connected to a musical instrument and inputs a sound signal of the musical instrument.

The sound signal processing of the mixer 1 is described with reference to FIGS. 2, 3, 4, 5, and 6. The sound signal processing referred to in this example is processing of changing the EQ curve (frequency characteristics) 31 displayed on the equalizer setting screen 20 by the user operation.

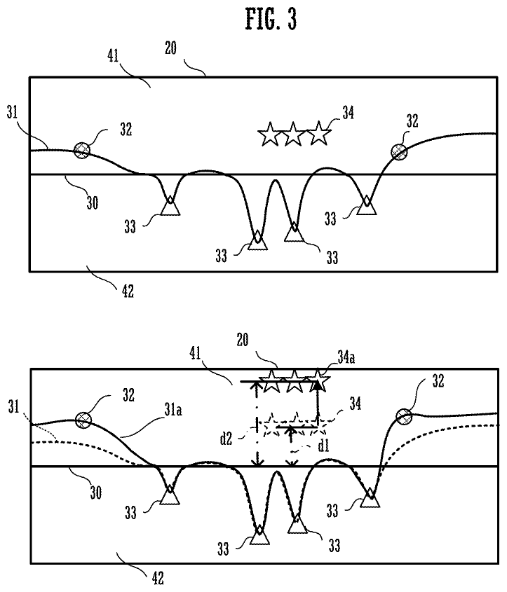

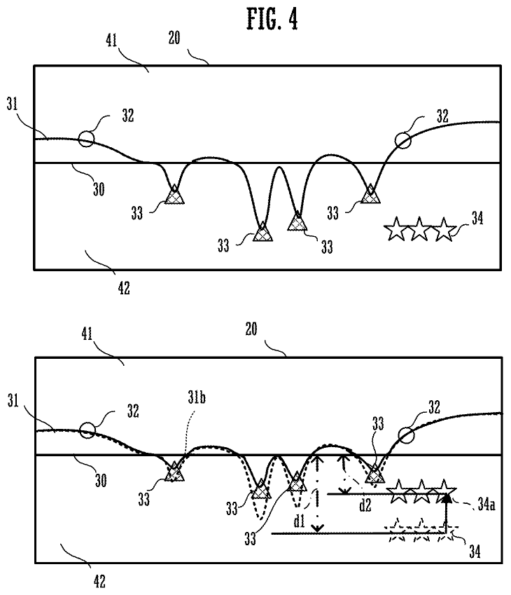

The upper diagram of FIG. 3 is an explanatory diagram showing an example of a first operation. The lower diagram of FIG. 3 is an explanatory diagram showing an example of a second operation. The upper diagram of FIG. 4 is an explanatory diagram showing an example of the first operation different from the example of FIG. 3. The lower diagram of FIG. 4 is an explanatory diagram showing an example of the second operation different from the example of FIG. 3. Star marks shown in FIGS. 2, 3 and 4 indicate the touch positions touched by the user. An EQ curve 31b in the lower diagram of FIG. 4 shows the EQ curve before the curve is changed.

The mixer 1 accepts, by the user operation, a plurality of setting points each setting a gain value for each frequency band. In other words, the mixer 1 sets, by the user operation, the plurality of setting points that accept changes in the EQ curve 31. For example, the user touch-operates on the EQ curve 31 corresponding to the frequency band whose gain value is desired to be adjusted. The mixer 1 sets the user touch position as setting points (two circles 32 and four triangles in the upper diagram of FIG. 3). One or more of the plurality of setting points are set, in each of the boost region 41 and the cut region 42 (see the upper diagram of FIG. 3).

The user sets a setting point by long-tapping, for example, a location (frequency) desired to set on the EQ curve 31. That is, the touch panel 15 acquires the coordinates of the long-tapped position as the coordinates of the setting point. The touch panel 15 acquires the coordinates of a plurality of setting points 32 (two in FIGS. 3 and 4) in the boost region 41 by the user performing the long tapping. Further, the touch panel 15 acquires the coordinates of a plurality of setting points 33 (four in FIGS. 3 and 4) in the cut region 42 by the user performing the long tapping. In this example, as shown in FIGS. 3 and 4, the setting points 32 set in the boost region 41 are represented by circle marks. Further, the setting points 33 set in the cut region 42 are represented by triangular marks. The setting points 32 belonging to the boost region 41 in this example each corresponds to the first setting point of the present disclosure. Further, the setting points 33 belonging to the cut region 42 in this example each corresponds to the second setting point of the present disclosure. The plurality of coordinates acquired by the touch panel 15 are stored in, for example, the flash memory 12 or the RAM 13.

The touch panel 15 accepts a first operation of selecting the plurality of setting points 32 belonging to the boost region 41 or the plurality of setting points 33 belonging to the cut region 42. More specifically, the touch panel 15 accepts the first operation of selecting all the setting points 32 belonging to the boost region 41 or all the setting points 33 belonging to the cut region 42. The first operation is a touch operation of multi-touching the boost region 41 or the cut region 42 with three fingers (hereinafter, the touching is referred to as a three-finger touch). Specifically, all the setting points 32 belonging to the boost region 41 or all the setting points 33 belonging to the cut region 42 are alternatively selected according to the touch position touched by the user with three fingers.

For example, when the user touches the boost region 41 with three fingers, the touch panel 15 accepts the selection of all the setting points 32 belonging to the boost region 41. That is, the touch panel 15 accepts the selection of all the setting points 32 belonging to the boost region 41 by accepting once the user performing the three-finger touch in the boost region 41. Further, when the user touches the cut region 42 with three fingers, the touch panel 15 accepts the selection of all the setting points 33 belonging to the cut region 42. The touch panel 15 accepts the selection of all the setting points 33 belonging to the cut region 42 by accepting once the user performing the three-finger touch in the cut region 42. In this way, when the touch panel 15 acquires the coordinates of the touch position, the CPU 11 determines whether the user has selected all the setting points 32 belonging to the boost region 41 or has selected all the setting points 33 belonging to the cut region 42.

The display 14 highlights all the setting points belonging to the region selected by the first operation (shaded circles in FIG. 3 or shaded triangles in FIG. 4).

Further, the touch panel 15 accepts the second operation of adjusting a gain value of each of the setting points. The second operation is a slide operation of sliding up and down the three touching fingers in the first operation as it is. The touch panel 15 sets the touch position of the first operation as an initial touch position 34, and accepts the vertical slide operation. When the touch panel 15 accepts the vertical slide operation, the CPU 11 adjusts the gain value of each of the setting points selected by the first operation.

Here, the CPU 11 adjusts the gain value of each of the setting points according to a ratio between before and after the sliding. The distance detector 111 of the CPU 11 detects a first distance d1 between the initial touch position 34 of the user and a position corresponding to the reference gain value 30. Further, the distance detector 111 detects a second distance d2 between a moving position 34a, which is a position after the sliding, and the position corresponding to the reference gain value 30 (see lower diagram of FIG. 3 and lower diagram of FIG. 4). In this example, the distance detector 111 detects the first distance d1 and the second distance d2 using the coordinates of the initial touch position 34 and the moving position 34a acquired by the touch panel 15. A mode for adjusting the gain value of each of the selected setting points according to the ratio between before and after the sliding in this example corresponds to the first adjustment mode of the present disclosure.

The gain value adjuster 112 of the CPU 11 adjusts the gain value of each of the selected setting points according to the ratio between the first distance d1 and the second distance d2. The ratio is calculated, for example, as d2/d1.

For example, when the user selects the boost region 41 in the first operation and slides the fingers upward at a ratio of 2 (d1:d2=1:2) in the second operation, as shown in FIG. 3, the gain value of each of the setting points 32 is doubled (from 6 dB to 12 dB). Further, when the user selects the cut region 42 in the first operation and slides the fingers upward at a ratio of 1/2 (d1:d2=1:1/2) in the second operation, as shown in FIG. 4, the gain value of each of the setting points 33 is halved (from −6 dB to −3 dB). The display 14 displays an EQ curve 31a corresponding to the adjusted gain value. Naturally, when the user slides the fingers downward, the gain value decreases in proportion to the distance that is slid.

Further, when the ratio becomes 0 (for example, d1=1, d2=0), the gain value adjuster 112 sets the gain value to 0 dB for each of the setting points adjusting the gain value.

The gain value adjuster 112 maintains the gain value of each of the setting points 32 in the boost region 41 to 0 dB even when the initial touch position 34 of the user is in the boost region 41 and the touch position of the slide operation goes beyond 0 dB and enters the cut region 42. That is, in this case, the gain value adjuster 112 sets the minimum value of the gain value to 0 dB. Further, the gain value adjuster 112 maintains the gain value of each of the setting points 33 in the cut region 42 to 0 dB even when the initial touch position 34 of the user is in the cut region 42 and the touch position of the slide operation goes beyond 0 dB and enters the boost region 41. That is, in this case, the gain value adjuster 112 sets the maximum value of the gain value to 0 dB.

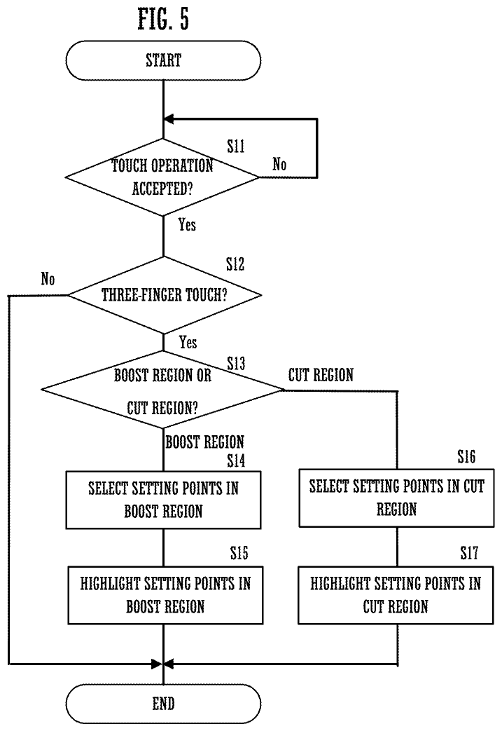

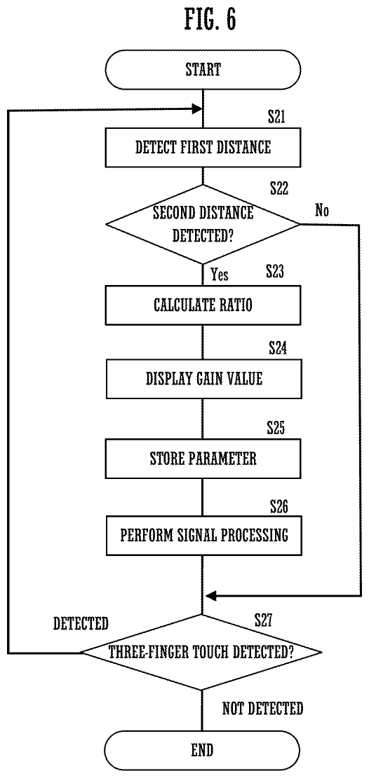

Hereinafter, the sound signal processing using the mixer 1 is described below with reference to FIGS. 5 and 6. FIG. 5 is a flowchart showing an example of an operation of the mixer 1 selecting the setting point. FIG. 6 is a flowchart showing an example of gain value adjustment processing.

The operation of the mixer 1 selecting the setting point is described with reference to FIG. 5. When accepting a touch operation (S11: Yes), the mixer 1 determines whether the touch operation is the three-finger touch (S12). When determining that the touch operation is the three-finger touch (S12: Yes), the mixer 1 determines whether the three-finger touch is performed in the boost region 41 or in the cut region 42 (S13). When the three-finger touch is determined to be performed in the boost region 41 (S13: boost region), the mixer 1 selects all the setting points 32 belonging to the boost region 41 (S14). The mixer 1 highlights all the setting points 32 belonging to the boost region 41 (S15).

On the other hand, when determining that the three-finger touch is performed in the cut region 42 (S13: cut region), the mixer 1 selects all the setting points 33 belonging to the cut region 42 (S16). The mixer 1 highlights all the setting points 33 belonging to the cut region 42 (S17).

The operation of the mixer 1 in the case of the slide operation being performed thereafter is described with reference to FIG. 6. In this example, a case where the user adjusts the gain values of all the setting points 32 belonging to the boost region 41 is described as an example. The mixer 1 detects the first distance d1 (S21). When detecting the mixer 1 the second distance d2 (S22: Yes), the mixer 1 adjusts the gain values of all the setting points 32 belonging to the boost region 41 according to the ratio between the first distance d1 and the second distance d2 (S23). The mixer 1 displays the adjusted gain values (S24). The mixer 1 stores the parameters corresponding to the adjusted gain values in the memory (RAM 13) (S25). The mixer 1 causes the DSP 17 to perform signal processing so as to give the sound signal the frequency characteristics corresponding to the changed parameters (S26). When the three-finger touch is no longer detected (S27: NOT DETECTED), the mixer 1 ends the processing related to the slide operation.

The same steps are performed in the case where the user adjusts the gain values of all the setting points 33 belonging to the cut region 42.

In the boost region 41, the user adjusts the frequency characteristics in order to adjust the sound quality and add tone to sound. In the cut region 42, the user adjusts the frequency characteristics in order to suppress howling. As described above, the purpose of adjusting the frequency characteristics is different between the boost region 41 and in the cut region 42. The user may want to emphasize or weaken the tone while maintaining the strength of howling suppression. Further, for example, the user may want to increase an amount of cut while maintaining the frequency characteristics of the boost region 41 and maintaining the tone when the howling is not completely suppressed, or may want to reduce the amount of cut because the howling is suppressed enough.

When the user selects all the setting points 32 belonging to the boost region 41, the mixer 1 can change the gain value can be changed only for all the setting points 32 belonging to the boost region 41. Further, when the user selects all the setting points 33 belonging to the cut region 42, the mixer 1 can change the gain value only for all the setting points 33 belonging to the cut region 42. Accordingly, the user can easily change only the gain values of the setting points belonging to either the boost region 41 or the cut region 42, depending on the purpose. Further, the mixer 1 can adjust the gain values while maintaining the ratio between the gain values of all the setting points 32 belonging to the boost region 41. That is, the user can change only the gain values while maintaining the tone that is once adjusted, and change only the degree of emphasizing the tone. Further, when the user selects all the setting points 33 belonging to the cut region 42, the mixer 1 can adjust only the gain values while maintaining the ratio between the gain values of all the setting points 33 belonging to the cut region 42. That is, the mixer 1 can adjust the gain values of the setting points collectively selected according to the purpose (emphasizing the tone or suppressing the howling).

The touch panel is not limited to the capacitive type, but may be a resistance film type, an ultrasonic surface sound wave type, or an optical type.

In addition, the setting of the setting point is not limited to the touch operation of long tapping on the EQ curve. The setting point may be set at a position on the EQ curve corresponding to a frequency at which the user wants to change the gain value, by the user performing a single touch operation on the frequency. However, the touch operations of the first operation and the second operation are preferably different from each other.

Further, the first operation is not limited to the touch operation of multi-touching with three fingers. The first operation may be the touch operation of multi-touching with two fingers, single-touching, or others. Further, the display 14 may display a “boost switch” button and a “cut switch” button on the equalizer setting screen 20. In this case, the mixer 1 may allow the user to selectively select the boost switch and the cut switch. In this case, the first operation is an operation in which the user touches the “boost switch” button or the “cut switch” button.

Further, the second operation is not limited to the vertical slide operation. For example, the second operation may be accepted using the operator 16, such as a knob or a fader, of the mixer 1.

Further, the touch panel 15 is not limited to the example in which the touch position of the first operation is accepted as the initial touch position 34 of the second operation. The touch panel 15 may accept, as the second operation, an operation in which the user touches the operation surface with three fingers, releases the finger from the operation surface once, and then touches and slides the operation surface again.

Further, the touch panel 15 may unset the setting point by, for example, the user long-tapping again the already accepted setting point.

Further, in the case of the user performing the single touch, the touch panel 15 may accept a change in center frequency of the gain value by the user scrolling the finger left and right.

Further, the touch panel 15 may accept a change in a Q value of the setting point by the user performing a pinch-in operation or a pinch-out operation.

Further, the touch panel 15 may accept operations other than the fingers of the user, such as a touch pen.

Highlighting is not limited to the above example. For example, when the user selects all the setting points 32 belonging to the boost region 41, the mixer 1 may reduce the brightness of the cut region 42 to emphasize the boost region 41.

Further, the touch panel 15 may accept the first operation of selecting some setting points 32 from among all the setting points belonging to the boost region 41. Further, the touch panel 15 may accept the first operation of selecting some setting points 33 from among all the setting points belonging to the cut region 42. When the user selects the boost region 41, the touch panel 15 may accept the first operation of selecting the setting points located at odd or even-numbered positions counted from the frequency of 20 Hz (the lowest frequency at which the equalizer can control the frequency characteristics) from among all the setting points 32 belonging to the boost region 41. Further, when the user selects the boost region 41, the touch panel 15 may accept the first operation of selecting the setting points exceeded a predetermined gain value or within a predetermined gain value, from among all the setting points 32 belonging to the boost region 41. Still further, the touch panel 15 may accept the first operation of selecting a predetermined number of setting points located in order from a position that the user has touched, or setting points located within a predetermined distance from the touch position that the user has touched among the target region.

When the user selects the cut region 42, the touch panel 15 may accept the first operation of selecting the setting points located at odd or even-numbered positions counted from the frequency of 20 Hz from among all the setting points 33 belonging to the cut region 42. Further, when the user selects the cut region 42, the touch panel 15 may accept the first operation of selecting the setting points exceeded a predetermined gain value or within a predetermined gain value, from among all the setting points 33 belonging to the cut region 42.

The parameter setting device includes: a setting point acceptor that accepts a plurality of setting points each setting a gain value for each band; an operation acceptor that accepts a first operation and a second operation, the first operation including selecting, from among the plurality of setting points that are accepted from a user, any one of a plurality of first setting points belonging to a region having a gain value higher than a reference gain value or a plurality of second setting points belonging to a region having a gain value lower than the reference gain value, and the second operation including adjusting the gain value of each of the plurality of first setting points or each of the plurality of second setting points selected; and a gain value adjuster that adjusts, according to the second operation, the gain value of each of the plurality of first setting points or each of the plurality of second setting points selected in the first operation.

In the parameter setting device, the first operation preferably selects all the first setting points belonging to the region having the gain value higher than the reference gain value, or all the second setting points belonging to the region having the gain value lower than the reference gain value.

Preferably, the operation acceptor further includes a distance detector that accepts a touch operation from the user, and in the second operation, detects a first distance between an initial touch position of the user and a position corresponding to the reference gain value, and a second distance between a position reached by maintaining touching from the initial touch position and the position corresponding to the reference gain value. The gain value adjuster preferably adjusts the gain value of the setting point according to the ratio between the first distance and the second distance.

Preferably, the parameter setting device further includes a display that displays the gain value for each band, the reference gain value, and the plurality of setting points on the screen. The operation acceptor preferably accepts the first operation and the second operation by accepting the touch operation of the user touching the touch panel.

The display preferably displays on the screen, a first region showing a region having a gain value higher than the reference gain value and a second region showing a region having a gain value lower than the reference gain value. When accepting a predetermined touch operation on the first region, the operation acceptor preferably accepts the predetermined touch operation as the first operation of selecting the plurality of first setting points in the first region. When accepting a predetermined touch operation on the second region, the operation acceptor preferably accepts the predetermined touch operation as the first operation of selecting the plurality of second setting points in the second region.

In the parameter setting device, the reference gain value is preferably 0 dB.

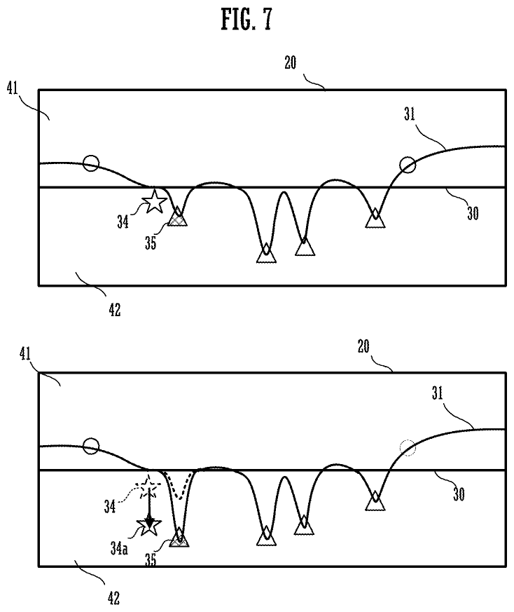

Another mixer 1 is described with reference to FIGS. 7, 8, 9, 10, 11, 12, and 13. The same constituents as those of the mixer 1 are designated by the same reference numerals and the descriptions thereof are omitted.

In this example, a touch panel 15 accepts a plurality of setting points, and then accepts a single touch, a touch with two fingers (hereinafter referred to as a two-finger touch), and a touch with three fingers (hereinafter, referred to as a three-finger touch), or a touch with four fingers (hereinafter referred to as a four-finger touch).

The single touch referred to in this example is an example of the first touch operation of the present disclosure. The four-finger touch referred to in this example is an example of the second touch operation of the present disclosure. The three-finger touch referred to in this example is an example of the fourth touch operation of the present disclosure.

Further, the touch panel 15 accepts a slide operation performed by the user when the one or plurality of setting points are selected by any one of the single touch, the three-finger touch, and the four-finger touch. The slide operation referred to in this example is an example of the third touch operation of the present disclosure.

The processing when the user performs the first touch operation is described with reference to FIG. 7. FIG. 7 is an explanatory diagram showing an example of adjusting the gain value of one setting point 35. In this example, the user performs the single touch to select one setting point 35 whose gain value is desired to be adjusted. As shown in FIG. 7, the touch panel 15 accepts an operation of selecting the closest setting point 35 from the touch position of the single touch.

When the touch panel 15 accepts a vertical slide operation after selecting the setting point 35 by the single touch, the touch position of the single touch is set to an initial touch position 34, and the touch panel 15 accepts the vertical slide operation. That is, when the user moves the finger up and down from the position of the single touch, a CPU 11 adjusts the gain value of the one selected setting point 35.

In this example, the CPU 11 adjusts the gain value of the setting point 35 according to the ratio between before and after the sliding. A gain value adjuster 112 adjusts the gain value of the one selected setting point 35 according to the ratio between a first distance d1 and a second distance d2 detected by a distance detector 111.

Further, when the touch panel 15 accepts a slide operation in the horizontal direction after the one setting point 35 is selected by the single touch, the CPU 11 changes the frequency of the one setting point according to the amount of horizontal sliding.

The touch panel 15 may accept an operation of selecting the setting point 35 by the user performing single touch (touching with one finger) on the setting point 35.

The processing when the user performs the three-finger touch is the same as that disclosed before. Therefore, the description is omitted.

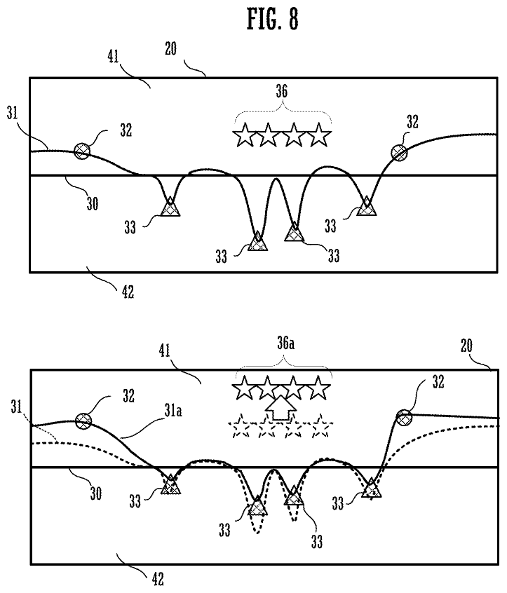

The processing when the user performs the four-finger touch is described with reference to FIG. 8. FIG. 8 is an explanatory diagram showing an example of adjusting the gain values of all setting points 32 and 33. The touch panel 15 accepts an operation of selecting all the setting points 32 and 33 belonging to a boost region 41 and a cut region 42 when the user touches any position of the touch panel 15 with four fingers. In FIG. 8, the initial touch position is an initial touch position 36, and the position after sliding is a moving position 36a.

The CPU 11 adjusts the gain value of all the selected setting points 32 and 33 by the user performing the slide operation.

The processing in the case of the user making the two-finger touch is described. The Q value is changed by the user pinching in or pinching out the touch panel 15 with two fingers. For example, in the case of the one setting point 35 being selected by the single touch, when the touch panel 15 accepts the pinch-in operation, the CPU 11 makes the Q value of the setting point 35 sharp. Further, when the touch panel 15 accepts the pinch-out operation, the CPU 11 makes the Q value of the setting point 35 blunt.

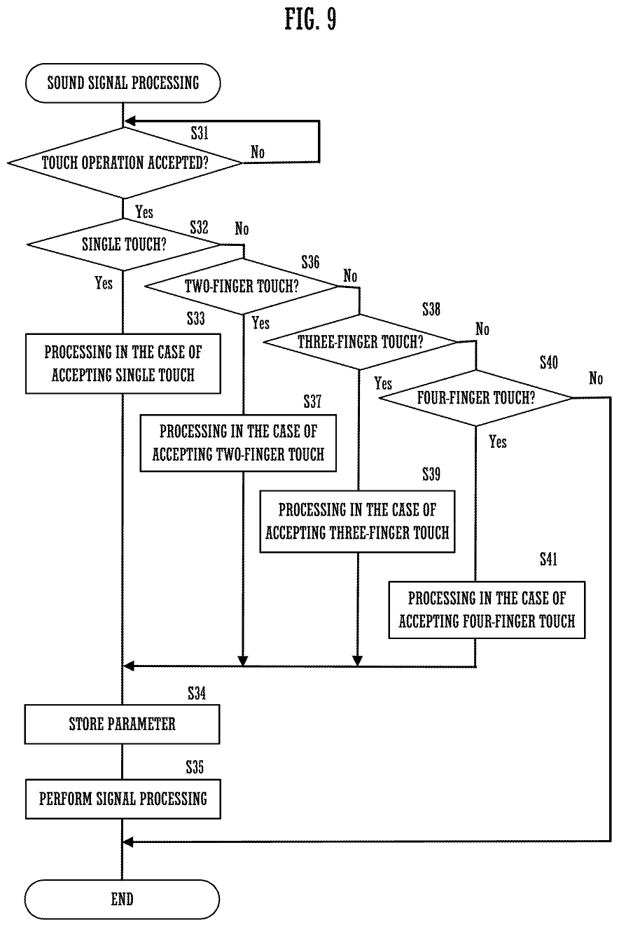

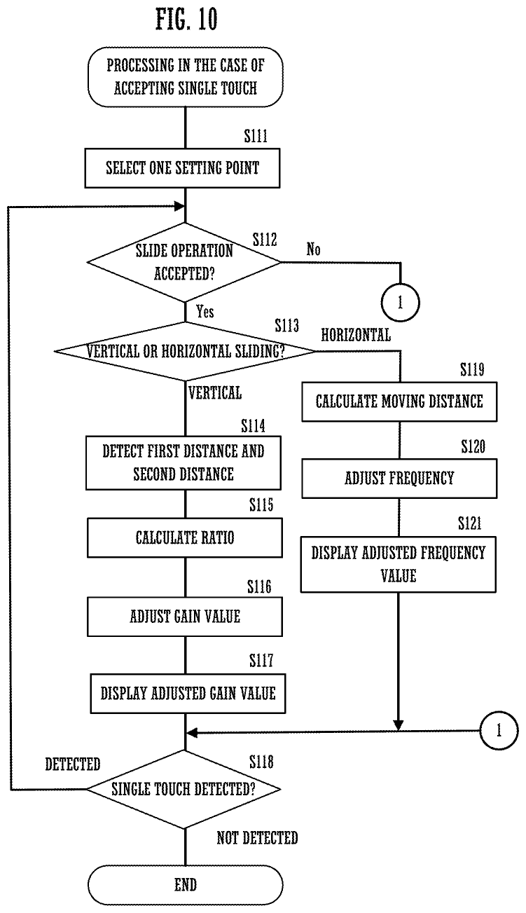

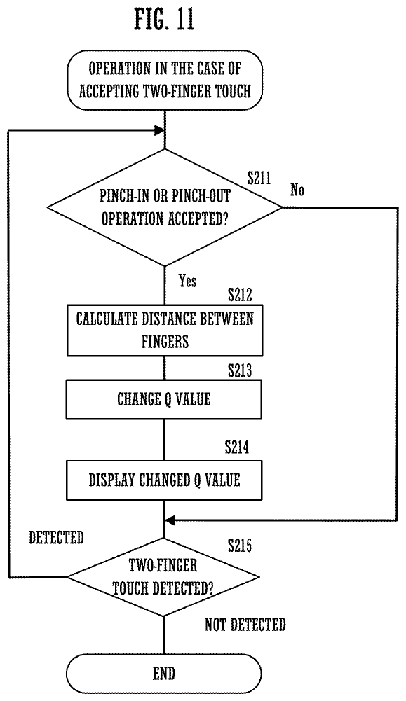

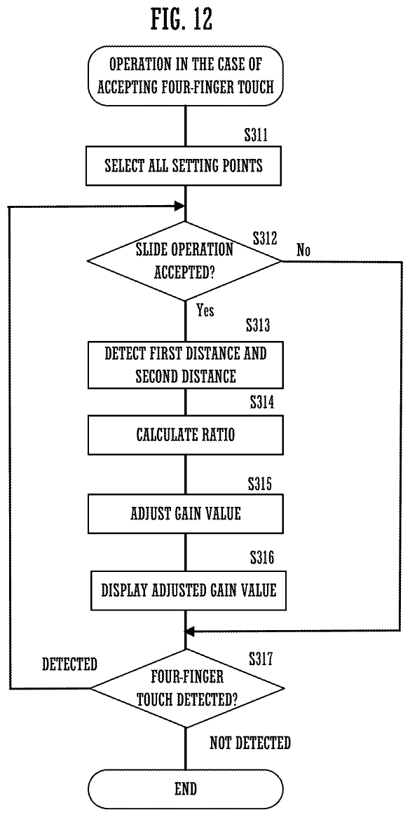

The sound processing of the mixer 1 is described with reference to FIGS. 9, 10 and 11. FIG. 9 is a flowchart showing an example of the sound processing of the mixer 1. FIG. 10 is a flowchart showing an example of the operation of the mixer 1 when the single touch is accepted. FIG. 11 is a flowchart showing an example of the operation of the mixer 1 when the two-finger touch is accepted. FIG. 12 is a flowchart showing an example of the operation of the mixer 1 when the four-finger touch is accepted.

After accepting the plurality of setting points, the mixer 1 determines whether or not the touch operation has been accepted as shown in FIG. 9 (S31). In the case of the mixer accepting the touch operation (S31: Yes), if the touch operation is a single touch (S32: Yes), processing in the case of accepting the single touch is performed (S33).

As shown in FIG. 10, when accepting the single touch, the mixer 1 selects one setting point 35 (S111). Thereafter, when accepting the slide operation (S112: Yes), the mixer 1 determines whether the slide operation is the vertical sliding or the horizontal sliding (S113). If the slide operation is performed in the vertical direction (S113: vertical), the mixer 1 detects a first distance d1 between the initial touch position 34 and a position corresponding to a reference gain value 30, and a second distance d2 between a moving position 34a which is a position after the sliding and the position corresponding to the reference gain value 30 (S114). The mixer 1 calculates the ratio between the first distance d1 and the second distance d2 which are detected (S115). The mixer adjusts the gain value of the selected setting point 35 according to the ratio (S116). The mixer 1 displays the adjusted gain value (S117). When the single touch is no longer detected (S118: NOT DETECTED), the mixer 1 stores the adjusted parameters in a memory (RAM 13) as shown in FIG. 9 (S34). The mixer 1 causes a DSP to perform signal processing so as to give the sound signal the frequency characteristics corresponding to the changed parameters (S35).

Further, if the slide operation is performed in the horizontal direction (S113: horizontal), the mixer 1 calculates a moving distance (amount of sliding) (S119). The mixer 1 adjusts the frequency of the selected setting point 35 according to the amount of sliding (S120). The mixer 1 displays one selected setting point such that the setting point is positioned at the adjusted frequency position (S121).

If the slide operation is no longer accepted (S112: No), the mixer 1 shifts the processing to S118. Further, if the single touch continues to be detected (S118: DETECTED), the mixer 1 shifts the processing to S112.

Further, if the touch operation is not the single touch but is the two-finger touch (S32: No, S36: Yes), the mixer 1 performs processing in the case of accepting the two-finger touch (S37).

When the pinch-in or pinch-out operation is accepted as shown in FIG. 11 (S211: Yes), the mixer 1 calculates the distance between the touching fingers (S212). In this case, the mixer 1 acquires and calculates the coordinates of the touch position touched by each finger. According to the calculated distance between the fingers, the mixer 1 changes the Q value of the one setting point 35 selected by the single-touch operation (S213). The mixer 1 displays the changed Q value for the setting point (S214). If the two-finger touch is no longer detected (S215: NOT DETECTED), the mixer 1 shifts the processing to S34.

Further, if the mixer 1 continues to detect the two-finger touch (S215: DETECTED), the process shifts to S211. Further, if the pinch-in or pinch-out operation is no longer accepted (S211: No), the mixer 1 shifts the processing to S215.

Further, if the touch operation is not the single touch nor the two-finger touch, but is the three-finger touch (S36: No, S38: Yes), the mixer 1 performs processing in the case of accepting the three-finger touch (S39). The mixer 1 selects either all the setting points 32 belonging to the boost region 41 or all the setting points 33 belonging to the cut region 42, according to the touch position of the three-finger touch. Because the processing of the three-finger touch is the same as that disclosed earlier, the description thereof is omitted.

In addition, if the touch operation is not the single touch, the two-finger touch, nor the three-finger touch, but is the four-finger touch (S38: No, S40: Yes), the mixer 1 performs the processing in the case of accepting the four-finger touch (S41).

The mixer 1 selects all the setting points 32 and 33 which are set, as shown in FIG. 12 (S311). When the slide operation is accepted (S312: Yes), the mixer 1 detects the first distance d1 between the initial touch position 34 and the position corresponding to the reference gain value 30, and the second distance d2 between the moving position 34a which is a position after the sliding and the position corresponding to the reference gain value 30 (S313). The mixer 1 calculates the ratio between the first distance d1 and the second distance d2 which are detected (S314). The mixer 1 adjusts the gain values of the selected setting points (all the setting points) 32 and 33 according to the ratio (S315). The mixer 1 displays all the setting points 32 and 33 so as to have the adjusted gain value (S316). If the four-finger touch is no longer detected (S317: NOT DETECTED), the mixer 1 shifts the processing to S34.

If the slide operation is not accepted (S312: No), the mixer 1 shifts the processing to S317. Further, if the four-finger touch continues to be detected (S317: DETECTED), the mixer 1 shifts the processing to S312.

By accepting various touch operations, the mixer 1 can select any of one setting point, all the setting points, all the setting points belonging to the boost region 41, or all the setting points belonging to the cut region 42 that the user desires. Further, the mixer 1 can adjust the Q value of the selected one setting point by accepting the pinch-in or pinch-out operation. Therefore, the mixer 1 can collectively adjust the gain values of a plurality of frequency bands depending the purpose of the user. Further, the mixer 1 can perform different operations on the same screen by accepting various touch operations without switching screens or functions.

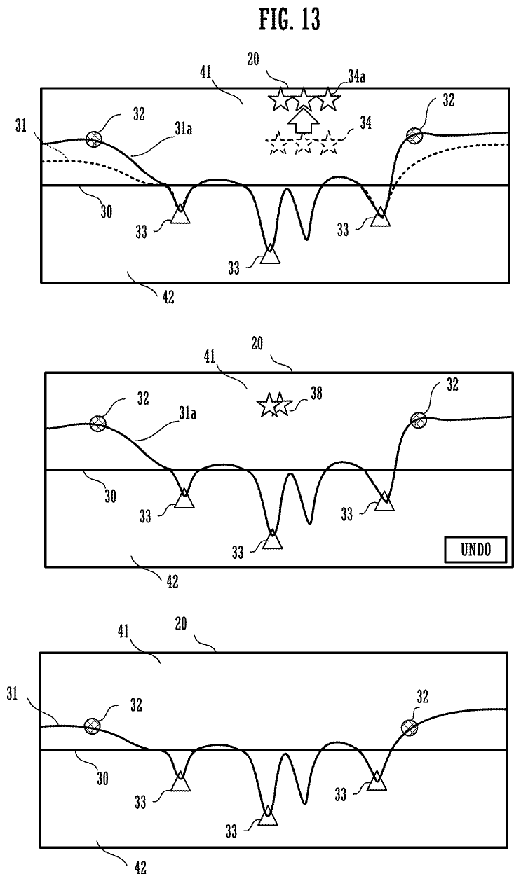

The mixer 1 may be configured to restore a changed EQ curve 31a to an original EQ curve 31 by the user double touching (tapping twice in succession in a short time) the touch panel 15 or by the user touching an undo button displayed on a display 14. FIG. 13 is an explanatory diagram showing an example of restoring the changed EQ curve 31a to an EQ curve obtained before being changed. The operation of double touching or touching the undo button in this example is an example of the fifth touch operation of the present disclosure.

When the setting point is selected by the three-finger touch or the four-finger touch, the CPU 11 stores the gain value (a parameter before adjustment) of the setting point selected at that time in the memory (RAM 13). When the touch panel 15 accepts the user performing the double touch or the touch operation of the undo button, the CPU 11 reads out the parameter before adjustment stored in the memory. The display 14 displays an equalizer screen that reflects the parameter before adjustment. Further, the CPU 11 causes the DSP 17 to perform signal processing so as to give the sound signal a frequency characteristics corresponding to the read parameter.

When the user touches the undo button to restore to the state before the user performs the operation, the mixer 1 deletes the undo button from the screen. In the case of the single touch, that is, if only one setting point is selected, the mixer 1 does not need to display the undo button or restore the EQ curve 31a changed by the double touch to the original EQ curve 31.

Further, when the number of touching fingers increases, the mixer 1 may determine the type of touch operation based on the number of touching fingers after the increase in number. That is, the mixer 1 performs processing according to the number of touching fingers after the increase in number. For example, when the mixer 1 accepts the three-finger touch and then accepts a touch of the fourth finger, the mixer 1 accepts the touch operation as the four-finger touch. However, it is preferable that the mixer 1 performs processing according to the number of touching fingers after the increase in number only when the number of touching fingers increases within a predetermined time period. Further, the mixer 1 preferably performs the processing according to the number of touching fingers after the increase in number only when the number of touching fingers increases before accepting the slide operation. In other words, the mixer 1 continues the operation performed before the number of touching fingers increases even if the number of touching fingers increases after accepting the slide operation.

Further, when the number of touching fingers decreases, the mixer 1 may set the touch panel 15 to a dead mode until all the fingers touching the touch panel 15 are released from the touch panel 15. The dead mode is a mode in which no operation, such as the touch operation and the slide operation from the user, other than the operation of releasing the finger from the touch panel 15 is accepted.

The three-finger touch and the four-finger touch are operations of selecting the plurality of setting points. On the other hand, the single touch and the two-finger touch are operations for changing the parameter of a specific setting point. Therefore, for example, even if the number of touching fingers in the three-finger touch is reduced by one and the touch with two fingers is accepted, the setting point to be pinched in or pinched out cannot be determined. In order to avoid such an operation, the mixer 1 preferably shifts to the dead mode when the number of touching fingers decreases.

The parameter setting device includes: a setting point acceptor accepting a plurality of setting points each setting a gain value for each band; and an operation acceptor that accepts a first touch operation of selecting a part of the setting points, a second touch operation of selecting all the setting points in a mode different from a mode of the first operation, and a third operation of adjusting the gain value of the one or plurality of setting points selected by the first touch operation or the second touch operation.

The operation acceptor preferably accepts from the user a fourth touch operation of selecting, from among the plurality of setting points that are accepted, any one of all the setting points belonging to a region having a gain value higher than a reference gain value, or all the setting points belonging to a region having a gain value lower than the reference gain value. Preferably, the third touch operation further adjusts the gain value of the setting point selected by the fourth touch operation.

The operation acceptor preferably accepts a fifth touch operation of restoring the gain value of the setting point that is selected to the gain value obtained before being adjusted by the third touch operation.

First Modification

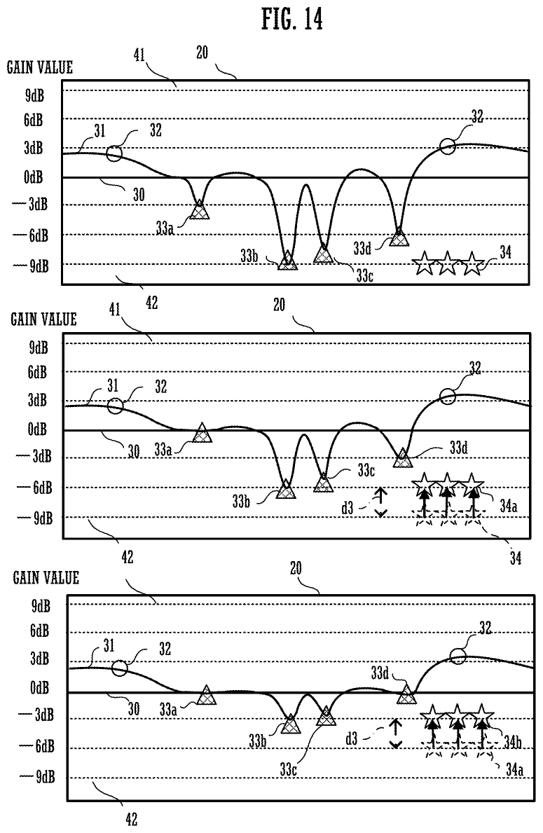

The gain value adjustment processing of a mixer 1 of the first modification is described with reference to FIG. 14. FIG. 14 is an explanatory diagram illustrating an operation of the gain value adjusting processing. The same constituents as those of the mixer 1 described above are designated by the same reference numerals and the descriptions thereof are omitted. The gain value adjustment processing referred to in this example corresponds to the second adjustment mode of the present disclosure.

The gain value adjustment processing of the first modification is different from the gain value adjustment processing disclosed above in that the gain value is adjusted according to a difference value, not according to the ratio between the amount of sliding.

In this example, as shown in FIG. 14, when the user selects all setting points (a setting point 33a, a setting point 33b, a setting point 33c, and a setting point 33d) belonging to a cut region 42 with the three-finger touch (selection touch operation), a CPU 11 adjusts the gain values of the setting point 33a, the setting point 33b, the setting point 33c, and the setting point 33d in the cut region 42 by an adjustment touch operation.

A distance detector 111 of the CPU 11 calculates an amount of sliding d3 obtained after sliding from an initial touch position 34 of the user. At this time, a gain value adjuster 112 adjusts the gain value corresponding to the amount of sliding by the slide operation.

For example, when the user moves the fingers upward from the position of −6 dB to the position of −3 dB on the screen, the gain values of the setting point 33a, the setting point 33b, the setting point 33c, and the setting point 33d in the cut region 42 move up by +3 dB.

Further, if the user continues to slide the fingers upward (see the lower diagram in FIG. 14), the gain value of the setting point 33a, which shows the highest gain value, first becomes 0 dB. In this case, the CPU 11 maintains the gain value of the setting point 33a not to exceed 0 dB even if the user further slides the fingers upward. That is, the gain value adjuster 112 sets the maximum value of the gain value to 0 dB.

In this case, for example, when the gain value of the setting point 33a becomes 0 dB and the user slides the fingers further upward, the gain value of the setting point 33a is maintained at 0 dB, whereas the gain values of the setting point 33b, the setting point 33c, and the setting point 33d keep increasing. In this way, when the gain value of the setting point 33a becomes 0 dB and the user slides the fingers further upward, the ratio between the gain values between the setting points collapses. Thereafter, if the user slides the fingers in the direction of lowering (restoring) the gain value to change the gain value according to the amount of sliding, the ratio between the gain values between the setting points remains collapsed. Therefore, the CPU 11 stores in the memory a gain ratio before the slide operation is started, and changes the gain value so as to reproduce the gain ratio.

More specific description is made below. For example, as shown in the upper diagram of FIG. 14, the case in which the initial value of the setting point 33a is −3 dB, the initial value of the setting point 33b is −9 dB, and the initial value of the setting point 33d is −6 dB is described (the initial value of the setting point 33c is any value between −6 dB and −9 dB). When the user slides the fingers upward by +3 dB on the screen, the gain value at setting point 33a first becomes 0 dB (middle diagram in FIG. 14). When the user slides the fingers further upward by +3 dB on the screen, the gain value of the setting point 33d also becomes 0 dB (lower diagram in FIG. 14). At this time, the gain value of the setting point 33a is maintained at 0 dB. The gain value of the setting point 33b is −3 dB. In this case, when the user slides the fingers downward, the ratio between the gain values collapses if the CPU 11 immediately changes the gain value of the setting point 33a according to the amount of sliding. Therefore, the CPU 11 first changes the gain values of the setting point 33b, the setting point 33c, and the setting point 33d according to the amount of sliding. Then, the CPU 11 changes the gain value of the setting point 33a according to the amount of sliding while maintaining the ratio between the gain values (if the setting point 33b exceeds −6 dB).

In the gain value adjusting processing, the gain values of all the selected setting points are adjusted at the same ratio. Therefore, the ratio between the gain values of the plurality of setting points does not collapse. On the other hand, the mixer 1 of the first modification adjusts the gain value of the setting point with the amount of sliding. Therefore, the user can more intuitively grasp the amount of change in the gain value. However, if there is a setting point that reaches 0 dB among a plurality of setting points, the ratio between the gain values becomes collapsed. The mixer 1 stores in the memory the ratio between the gain values of the setting point 33a, the setting point 33b, the setting point 33c, and the setting point 33d in the state before the gain value is changed. Therefore, the mixer 1 can adjust the gain values of all the setting points that are selected while maintaining the ratio between the gain values.

The parameter setting device includes: a setting point acceptor that accepts a plurality of setting points each setting a gain value for each band; an operation acceptor that accepts from a user, a first touch operation of selecting one or a plurality of setting points, and a second touch operation of adjusting the gain value of the one or plurality of setting points selected by the first operation; a distance detector that detects, in the second touch operation, a first distance between an initial touch position of the user and a position corresponding to a reference gain value, and a second distance between a position reached by maintaining touching from the initial touch position and the position corresponding to the reference gain value; and a gain value adjuster that performs a first adjustment mode of adjusting the gain value of the one or plurality of setting points selected by the first operation according to a ratio between the first distance and the second distance.

The gain value adjuster preferably performs any one of the first adjustment mode or a second adjustment mode of adjusting the gain values of the one or plurality of setting points selected by the first touch operation according to the distance from the initial touch position of the user to the position reached by maintaining touching.

The gain value adjuster preferably adjusts the gain value of the one or plurality of setting points in the second adjustment mode so as not to exceed the reference gain value.

Second Modification

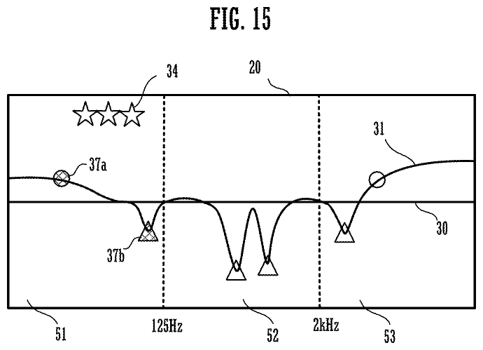

A mixer 1 of the second modification is described with reference to FIG. 15. FIG. 15 is an explanatory diagram showing an equalizer setting screen 20 for gain values of the second modification. The same constituents as those of the mixer 1 and the first modification described above are designated by the same reference numerals and the descriptions thereof are omitted.

In this example, as shown in FIG. 15, the equalizer setting screen 20 has distinct regions for selecting the setting points, according to the frequency bands. The equalizer setting screen 20 is divided into, for example, a low range (125 Hz or less) 51, a midrange (125 Hz to 2 kHz) 52, and a high range (2 kHz or more) 53.

When accepting a touch operation by the user in the low range 51, the midrange 52, or the high range 53, the touch panel 15 accepts all the setting points belonging to the region that the user has touched (the low range 51, the midrange 52, or the high range 53). For example, the user performs a touch operation, which is the first operation, on the low range 51. The touch panel 15 accepts the selection of all (two in FIG. 15) setting points 37a and 37b in the low range 51 that the user has touched.

In this case, the equalizer setting screen 20 is divided according to the frequency bands, and the touch panel 15 accepts the selection of all the setting points belonging to the region that the user has touched. As a result, the mixer 1 allows the user to collectively set the setting points in the frequency band range.

The number of divided regions is not limited to the above. The equalizer setting screen 20 may be divided into two or four or more regions.

Further, the mixer 1 may set the regions of the equalizer setting screen 20 according to the type of musical instrument. In this case, the mixer 1 sets the regions according to the type of musical instrument (for example, the name of the musical instrument) of an audio signal input from an I/O 18. For example, the mixer 1 may divide the equalizer setting screen 20 into a fundamental tone region that is the frequency band of the fundamental tone of the musical instrument and a harmonic overtone region that is involved in the tone of the musical instrument.

Further, the relationship between each region and the frequency band is not limited to the division of the above-described example (125 Hz or less, 125 Hz to 2 kHz, and 2 kHz or more). For example, the mixer 1 may be configured to have regions divided according to the frequency bands that the user desires. Third Modification

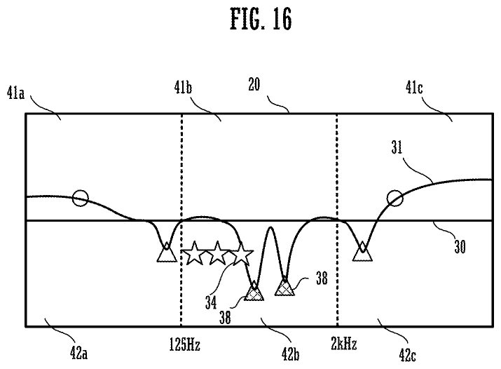

A mixer 1 of the third modification is described with reference to FIG. 16. FIG. 16 is an explanatory diagram showing an equalizer setting screen 20 for gain values of the third modification. The same constituents as those of the mixer 1 and the first and second modifications are designated by the same reference numerals and the descriptions thereof are omitted.

As shown in FIG. 16, the equalizer setting screen 20 has distinct regions for selecting the setting points, according to gain values (boost value or cut value) and frequency bands. On the boost side, the equalizer setting screen 20 is divided into a boost-side low range 41a, a boost-side midrange 41b, and a boost-side high range 41c. Further, on the cut side, the equalizer setting screen 20 is divided into a cut-side low range 42a, a cut-side midrange 42b, and a cut-side high range 42c.

When accepting the touch operation by the user, the touch panel 15 accepts selection of all the setting points belonging to the region that the user has touched. For example, the user performs a touch operation, which is the first operation, on the cut-side midrange region 42b. The touch panel 15 accepts the selection of all (two in FIG. 16) setting points in the cut-side midrange region 42b that the user has touched.

In this way, the equalizer setting screen 20 is divided according to the gain values and the frequency bands, and the touch panel 15 accepts the selection of all the setting points belonging to the region that the user has touched. As a result, the mixer 1 allows the user to collectively set the setting points in a finer range.

The number of divided regions is not limited to the above. The equalizer setting screen 20 may be divided into four, five, or seven or more regions.

Further, the mixer 1 may set the regions of the equalizer setting screen 20 according to the type of musical instrument. In this case, the mixer 1 sets the regions according to the type of musical instrument (for example, the name of the musical instrument) of an audio signal input from an I/O 18. For example, the mixer 1 may divide the equalizer setting screen 20 into a fundamental tone region that is the frequency band of the fundamental tone of the musical instrument and a harmonic overtone region that is involved in the tone of the musical instrument.

Further, the relationship between each region and the frequency band is not limited to the division of the above-described example (125 Hz or less, 125 Hz to 2 kHz, and 2 kHz or more). For example, the mixer 1 may be configured to have regions divided according to the frequency bands that the user desires.

Further, when, for example, the user touches the cut-side midrange 42b, the touch panel 15 may select only some of the setting points from among all (two in FIG. 16) the setting points belonging to the cut-side midrange 42b. Further, in this case, the mixer 1 switches the setting point each time the user touches the region. The descriptions of the present embodiments should be considered as exemplary in all respects and not restrictive.

The scope of the present disclosure is defined by the scope of the claims, rather than the embodiments described above. Further, the scope of the present disclosure is intended to include meanings equivalent to the claims and all modifications within the scope.

What is claimed is:

1. A sound processing method, comprising:
accepting a plurality of setting points each setting a gain value for each band;
accepting from a user a first operation and a second operation, the first operation including selecting any one of a plurality of first setting points belonging to a region having a gain value higher than a reference gain value or a plurality of second setting points belonging to a region having a gain value lower than the reference gain value, and the second operation including adjusting the gain value of each of the plurality of first setting points or each of the plurality of second setting points selected; and
adjusting the gain value of each of the plurality of first setting points or each of the plurality of second setting points selected in the first operation according to the second operation.

2. The sound processing method according to claim 1, wherein the first operation includes selecting all the first setting points belonging to the region having the gain value higher than the reference gain value or all the second setting points belonging to the region having the gain value lower than the reference gain value.

3. The sound processing method according to claim 1, further comprising:
accepting a touch operation from the user;
detecting, in the second operation, a first distance between an initial touch position of the user and a position corresponding to the reference gain value, and a second distance between a position reached by maintaining touching from the initial touch position and the position corresponding to the reference gain value; and
adjusting the gain value of the setting point according to a ratio of the first distance to the second distance.

4. The sound processing method according to claim 1, further comprising:
displaying the gain value for each band, the reference gain value, and the plurality of setting points on a screen; and
accepting the first operation and the second operation by accepting from the user a touch operation of touching the touch panel.

5. The sound processing method according to claim 4, further comprising:
displaying on the screen, a first region showing a region having a gain value higher than the reference gain value and the second region showing a region having a gain value lower than the reference gain value; and
when a predetermined touch operation on the first region is accepted, accepting the predetermined touch operation as the first operation of selecting the plurality of first setting points in the first region, or when a predetermined touch operation on the second region is accepted, accepting the predetermined touch operation as the first operation of selecting the plurality of second setting points in the second region.

6. The sound processing method according to claim 1, wherein the reference gain value is 0 dB.

7. A sound processing method, comprising:
accepting a plurality of setting points each setting a gain value for each band; and
accepting from a user a first touch operation selecting a part of the setting points, a second touch operation selecting all the setting points in a mode different from a mode of the first operation, and a third operation adjusting the gain value of the one or plurality of setting points selected by the first touch operation or the second touch operation.

8. The sound processing method according to claim 7, further comprising accepting from the user a fourth touch operation selecting, from among the plurality of setting points that are accepted, any one of all the setting points belonging to a region having a gain value higher than a reference gain value, or all the setting points belonging to a region having a gain value lower than the reference gain value,
wherein the third touch operation further includes adjusting the gain value of the setting point selected by the fourth touch operation.

9. The sound processing method according to claim 7, further comprising accepting a fifth touch operation restoring the gain value of the setting point that is selected to the gain value obtained before being adjusted by the third touch operation.

10. A sound processing method, comprising:
accepting a plurality of setting points each setting a gain value for each band;
accepting from a user, a selection touch operation selecting one or a plurality of setting points, and an adjustment touch operation adjusting the gain value of each of the one or plurality of setting points selected by the selection touch operation;
detecting, in the adjustment touch operation, a first distance between an initial touch position of the user and a position corresponding to a reference gain value, and a second distance between a position reached by maintaining touching from the initial touch position and the position corresponding to the reference gain value; and
performing a first adjustment mode adjusting the gain value of the one or plurality of setting points selected by the selection touch operation according to a ratio of the first distance to the second distance.

11. The sound processing method according to claim 10, further comprising performing any one of the first adjustment mode or a second adjustment mode of adjusting the gain value of each of the one or plurality of setting points selected by the selection touch operation according to a distance from the initial touch position of the user to the position reached by maintaining the touching.

12. The sound processing method according to claim 11, further comprising adjusting the gain value of each of the one or plurality of setting points in the second adjustment mode so as not to exceed the reference gain value.
